(19) United States
(12) Patent Application Publication
(10) Pub. No.: US 2009/0016074 A1
(43) Pub. Date: Jan. 15, 2009

(54) Semiconductor light engine using glass light pipes

(75) Inventors: Micheal D. Dolson, Corbyville (CA); Ronald O. Woodward, Yorktown, VA (US)

Correspondence Address: WARN, HOFFMANN, MILLER & LALONE, .P.C, PO BOX 70098, ROCHESTER HILLS, MI, 48307, US

(73) Assignee: Magna International Inc., Aurora (CA)

(21) Appl. No.: 11/894,178

(22) Filed: Aug. 20, 2007

Related U.S. Application Data
(63) Continuation-in-part of application No. 11/825,732, filed on Jul. 9, 2007, now abandoned.

(51) Int. Cl. F21V 29/00; H01L 33/00

(52) U.S. Cl. 362/555; 362/580

(57) ABSTRACT

A light engine for use in systems such as automotive lighting systems employs two or more semiconductor light sources, such as LEDs. Light emitted from the light sources is captured by light pipes which are mounted such that the light capturing surface of the light pipes are properly positioned, with respect to the semiconductor light sources. The light pipes transfer substantially all of the light captured from the semiconductor light sources to light emitting surfaces of the light pipes which can be appropriately located adjacent the output optics of the lighting system. The light engine can be easily assembled as the light pipes are in modules including a carrier member that can be mounted to a positioning member which also includes apertures to position the light capture surfaces of the light pipes at a known position with respect to the semiconductor light sources.

### CROSS-REFERENCE TO RELATED APPLICATIONS

This application is a continuation-in-part of U.S. patent application Ser. No. 11/825,732 filed on Jul. 9, 2007. The disclosure of the above application is incorporated herein by reference.

### FIELD OF THE INVENTION

The present invention relates to a light engine employing semiconductor light sources to produce light. More specifically, the present invention relates to a light engine comprising a plurality of semiconductor light sources each of whose emitted light is transferred from the semiconductor source to a respective desired destination via a respective light pipe.

### BACKGROUND OF THE INVENTION

With the development of semiconductor light sources, such as light emitting diodes (LEDs), which can output relatively high levels of white light, the development of automotive lighting systems, such as headlamp systems, which employ such semiconductor light sources has become possible. However, lighting systems employing semiconductor light sources have proven to be difficult to design and construct as, even with the most advanced semiconductor light sources, multiple sources typically must be employed to obtain the necessary light output levels. Also, unlike prior light sources such as incandescent or gas discharge bulbs which served as single, generally very bright, light sources, semiconductor light sources act as multiple point sources of light and thus the design of the lighting system must differ from conventional designs.

In many of the lighting system designs developed by the assignee of the present invention, a light pipe is employed to capture the light emitted from the semiconductor light source and to transfer that light into the lighting system's optical path which can be a lens, or set of lenses, etc. As the amount of light emitted by the semiconductor light sources is relatively low, the design, manufacture and positioning of these light pipes in the lighting system is important to the effectiveness of the lighting system.

Further, as a lighting system may include many semiconductor light sources and their corresponding light pipes, the cost effective manufacture and assembly of these lighting systems has been challenging. In particular, developing a cost effective system for using light pipes formed from relatively delicate and/or hard to shape optical glass and mounting these light pipes with a mounting system that does not substantially degrade the amount of light transferred through the light pipe has proven difficult. It has also proven difficult to develop such a system which can maintain the desired spacing of the light pipes with respect to the semiconductor light sources over the expected wide range of operating temperatures in automotive lighting applications.

It is desired to have a lighting system employing semiconductor light sources which is relatively cost effective to manufacture, assemble and employ.

### SUMMARY OF THE INVENTION

It is an object of the present invention to provide a novel automotive lighting system employing semiconductor light sources which obviates or mitigates at least one disadvantage of the prior art.

According to a first aspect of the present invention, there is provided a light engine comprising: at least two semiconductor light sources; a heat sink in thermal communication with the at least two semiconductor light sources to remove waste heat therefrom; a positioning member including a set of positioning apertures, the positioning member mounted with respect to the at least two semiconductor light sources such that respective positioning apertures are closely aligned with corresponding light emitting surfaces of the at least two semiconductor light sources; and a light pipe module comprising at least two light pipes, each light pipe including an optical portion, having a light capturing surface and a light emitting surface, and a non-optical portion to mount the light pipe, the light pipe module including a carrier member formed over the non-optical portion of each light pipe, the carrier member maintaining the light pipes in a desired orientation and having a mounting portion to engage the positioning member such that the light capturing surface of each light pipe in the module is positioned in a respective positioning aperture adjacent the light emitting surface of the semiconductor light source.

According to another aspect of the present invention, there is provided an automotive lighting system, comprising: a base member; a transparent cover member joined to the base member and forming an optics chamber therebetween; a rear cover joined to the base member and cover member to form a rear chamber adjacent the optics chamber; a mounting bracket and flexible moveably attached to the base member, the mounting bracket having mounted to it a light engine and an optics system, the mounting bracket, flexible gasket and light engine separating the optics chamber from the rear chamber and the light engine comprising: at least two semiconductor light sources; a heat sink in thermal communication with the at least two semiconductor light sources to remove waste heat therefrom; a positioning member including a set of positioning apertures, the positioning member mounted with respect to the at least two semiconductor light sources such that respective positioning apertures are closely aligned with corresponding light emitting surfaces of the at least two semiconductor light sources; and a light pipe module comprising at least two light pipes, each light pipe including an optical portion, having a light capturing surface and a light emitting surface, and a non-optical portion to mount the light pipe, the light pipe module including a carrier member formed over the non-optical portion of each light pipe, the carrier member maintaining the light pipes in a desired orientation and having a mounting portion to engage the positioning member such that the light capturing surface of each light pipe in the module is positioned in a respective positioning aperture adjacent the light emitting surface of the semiconductor light source.

The present invention provides a light engine for use in systems such as automotive lighting systems which employ two or more semiconductor light sources, such as LEDs. Light emitted from the light sources is captured by light pipes which have been overmolded to form a light pipe module which maintains the relative positioning of the light emitting ends of the light pipes. A positioning member includes apertures to engage the edges of the light receiving portion of the light pipes, the apertures being positioned to ensure that the light receiving portions of the light pipes are positioned as desired with respect to the light emitting surface of the semiconductor light sources. The light pipes transfer substantially all of the light captured from the semiconductor light sources to light emitting surfaces of the light pipes which are appropriately located adjacent the output optics of the lighting system. The light engine can be easily assembled with the module holding the light pipes and locating the light emitting ends of the light pipes as desired while the apertures of the positioning member position the light receiving ends of the light pipes.

### BRIEF DESCRIPTION OF THE DRAWINGS

Preferred embodiments of the present invention will now be described, by way of example only, with reference to the attached Figures, wherein:

FIG. 1 is an exploded perspective view of a light engine in accordance with the present invention;

FIG. 2 is a perspective view of the assembled light engine of FIG. 1;

FIGS. 3a and 3b are perspective views showing more detail of a light pipe employed in the light engine of FIG. 1;

FIG. 4a shows a section through the light emitter surface of a light pipe;

FIG. 4b shows a section through the light emitter surface of a preferred embodiment of a light pipe;

FIG. 5 shows a light pipe module employed in the light engine of FIG. 1; and

FIG. 6 shows a cross section through a lighting system employing the light engine of FIG. 1.

### DETAILED DESCRIPTION OF THE PREFERRED EMBODIMENTS

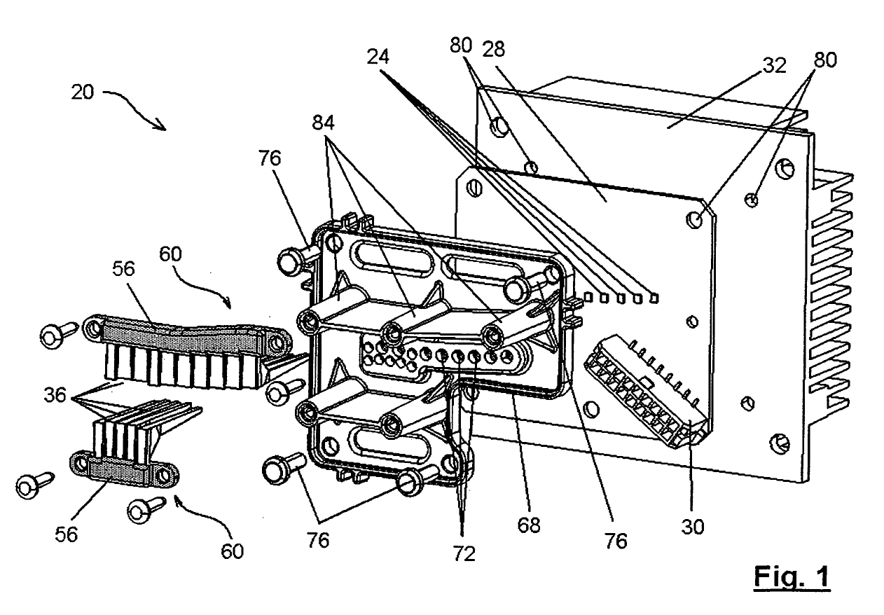

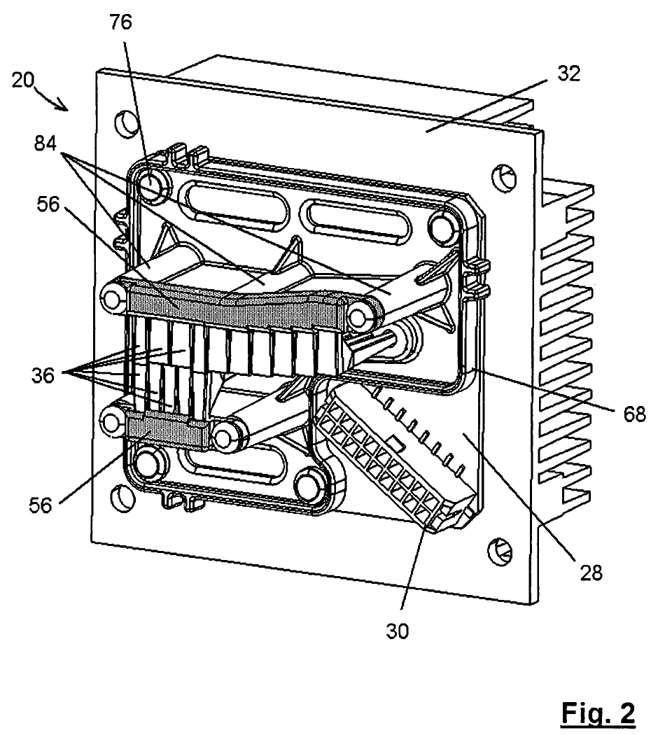

A light engine in accordance with the present invention is indicated generally at 20 in FIGS. 1 and 2. As will be apparent to those of skill in the art, one or more light engines 20 can be combined with an optics system, such as a lens or set of lenses, and an enclosure to form automotive lighting systems, such as headlamps, etc.

Light engine 20 includes a set of semiconductor light sources, which in this embodiment are LEDs 24, that emit the light provided by light engine 20. LEDs 24 are mounted on a substrate 28, which can be an electrical circuit board or other suitable mounting element. Preferably, substrate 28 includes the necessary electrical circuit connectors to supply power to LEDs 24 from an appropriate connector 30 or other power source.

As is known to those of skill in the art, the expected operating lifetime of semiconductor light sources is dependent upon the operating temperature of their semiconductor junction and it is thus important that heat be effectively removed from LEDs 24. Accordingly, substrate 28 preferably facilitates, or enhances, the transfer of heat from LEDs 24 to a heat sink 32.

Heat sink 32 can be manufactured in any appropriate manner of any suitable material as will occur to those of skill in the art. In the illustrated embodiment, heat sink 32 is an extruded aluminum member which includes a substantially flat surface, to which substrate 28 is attached, and an opposed surface from which a set of upright cooling fins extend. Heat sink 32 can of course assume a variety of other configurations, including configurations which also include cooling fans, heat wick systems, liquid cooling systems, etc. and the present invention is not limited to any particular configuration of heat sink 32 or substrate 28.

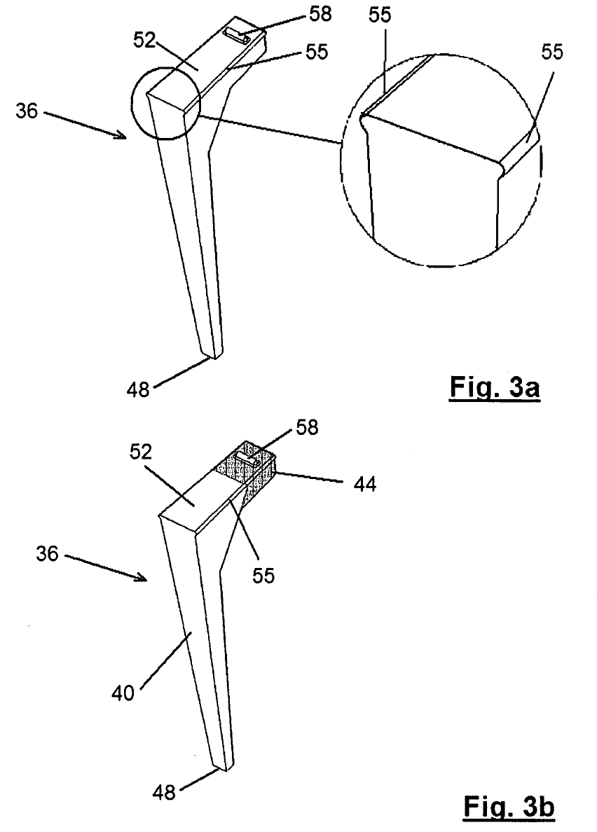

Light engine 20 includes a plurality of light pipes 36, the detail of which is best seen in FIGS. 3a and 3b, that operate to transfer the light emitted from LEDs 24 to a desired output location, typically adjacent an optical system (not shown) which can comprise one or more lenses, etc. Each light pipe 36 includes both an optical portion 40 and a mounting portion 44 (indicated with the stippled pattern in FIG. 3b).

Optical portion 40 includes a light capture surface 48 and a light emitter surface 52 and optical portion 40 is formed with a smooth, lens-like finish and with as few optical flaws as possible. Mounting portion 44 need not have the smooth finish of optical portion 40 and manufacturing flaws can be accommodated in mounting portion 44.

Light pipes 36 are designed such that substantially all of the light entering light capture surface 48 is transferred through light pipe 36 via total internal reflection and is emitted from light emitter surface 52. To efficiently capture as much of the light emitted by LEDs 24 as possible, light capture surface 48 of each respective light pipe 36 must be carefully positioned with respect to the light emitting surface of its corresponding LED 24. Ideally, light capture surface 48 is centered over the light emitting surface of the corresponding LED 24, at a desired air gap spacing between light capture surface 48 and the light emitting surface of LED 24.

In a present embodiment of the invention, light pipes 36 are formed by first casting a light pipe blank from an optical grade soda glass supplied by Moulded Optics GmbH, Steinstraβe 15, D-35641 Schöffengrund, Germany. As will be apparent to those of skill in the art, other optical grade glasses can be employed depending on the characteristics desired between the light pipes 36 and light engine 20. For example having similar thermal expansion characteristics can be one desired characteristic.

Once the light pipe blanks are cast, they are then tempered, removed from their blanks, ground to shape and at least the optical portion 40 of each light pipe 36 is diamond polished to obtain the desired lens-like finish and optically flat surfaces which enhance the transmission of light from light capture surface 48 to light emitter surface 52.

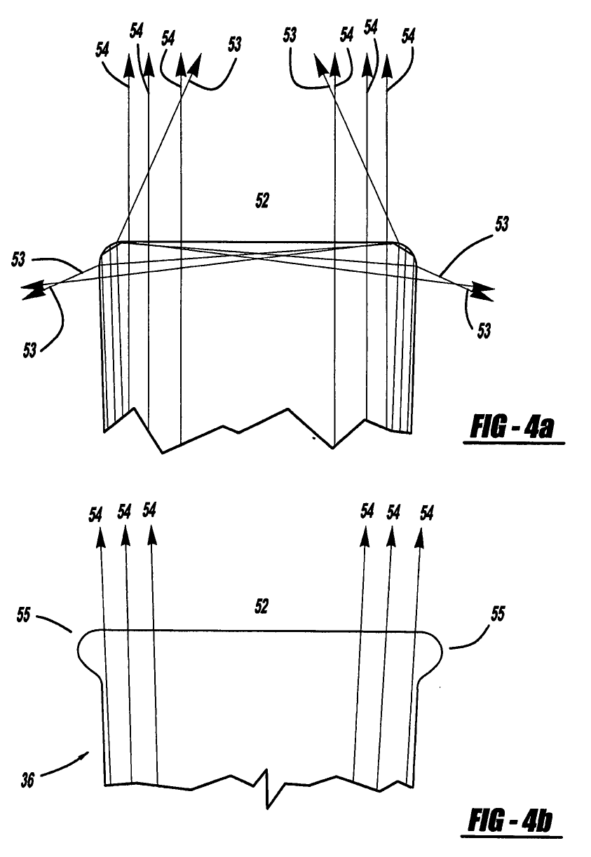

When casting the light pipes, the resulting edges of the blanks are formed with radii of between 0.003 inches to 0.005 inches. Radii such as these at the edges of light emitting surface 52 can result in a relatively significant loss of useful light from light emitter surface 52 of light pipes 36 due to scatter. Specifically, as shown in FIG. 4a, if a light pipe was formed with such radii at the edges of light emitting surface 52, light 53 emitted from the light pipe 36 at the edges would be scattered by the radii rather than the light 54 which is emitted, as desired, from the rest of light emitter surface 52.

While the edges of the light pipe at light emitting surface 52 can be ground and polished to remove the radii to prevent this scattering, and one surface of light pipes 36 is ground and polished as a necessary step in removing the light pipe 36 from its blank, these grinding and polishing operations add a significant expense to the manufacture of light pipes 36.

In the present embodiment of light pipes 36, scatter will not occur from light emitter surface 52 adjacent the non-optical portion 44, as the radii is at the outer edge of non-optical portion 44, well beyond the surface region from which light will be emitted.

Also, as mentioned above, when light pipe 36 is cast and removed from its blank, the surface (opposite non-optical portion 44) which was attached to the blank is ground and polished. Thus, in the embodiment illustrated in FIGS. 3a and 3b, the undesired radii only affect the two edges of light emitter surface 52 which extend from non-optical portion 44 towards the ground and polished surface of light pipe 36.

In order to avoid the undesired expense and to prevent scattering from these two edges, light pipes 36 are cast with a lip 55 about the two edges of light emitter surface 52. As shown in FIG. 4b, and in FIGS. 3a and 3b, lips 55 result in the undesired radii being outside the surface region of light emitter surface 52 where light is expected to be emitted and thus substantially all of light 54 is emitted without undesired scatter.

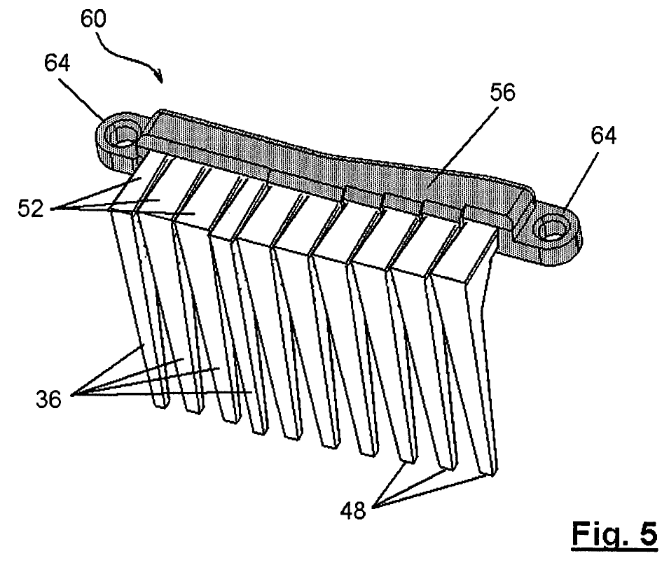

Light pipes 36 are generally fragile and care is required when handling light pipes 36 and assembling light engine 20. Accordingly, as shown in the FIG. 5, in the present invention a plurality of light pipes 36 are placed into a holding jig (not shown) and a carrier member 56 is overmolded onto the mounting portions 44 of the light pipes 36 to form a light pipe module 60. The overmolded material engages a feature, such as holding boss 58, which is formed on mounting portion 44 which locks each light pipe 36 to carrier member 56.

The holding jig positions optical portion 40 of each light pipe 36 in a desired position with respect to each other light pipe 36 and with respect to the location that the mounting portions 64 of carrier member 56 will be formed at. The holding jig also holds each light pipe 36 such that, when module 60 is mounted in light engine 20, each respective light capture surface 48 will be at the desired height above its respective LED 24.

Carrier member 56 can be fabricated from any suitable thermoplastic material and, in the embodiment discussed, is formed from polycarbonate as this has similar thermal expansion characteristics as the soda glass from which light pipes 36 are formed. Carrier member 56 does not contact the optical portion 40 of light pipes 36 and thus does not affect the total internal reflection which is employed through optical portion 40 to transfer the light received at capture surface 48 to light emitting surface 52.

As is shown in FIG. 5, module 60 can include light pipes 36 having differing thicknesses and/or widths of light emitting surfaces 52 to transfer light from LEDs 24 to the optical system of the headlamp or other optical system to achieve a desired output beam pattern.

Referring again now to FIGS. 1 and 2, light engine 20 further includes a positioning member 68 which is mounted to substrate 28. Positioning member 68 includes a set of positioning apertures 72, one positioning aperture 72 for each LED 24 on substrate 28. Positioning member 68 is positioned on substrate 28, such that each positioning aperture 72 closely encircles the light emitting surface of a respective LED 24. Preferably, positioning member 68 includes a set of index features, such as the illustrated mounting posts 76 or the like, which engage complementary indexing features, such as mounting apertures 80 on substrate 28 and/or heat sink 32 such that positioning member 68 can be easily and fixedly mounted to substrate 28 with apertures 72 correctly aligned with the respective LEDs 24.

Positioning apertures 72 act to correctly position the light capture surface 48 of each respective light pipe 36 over the light emitting surface of a respective LED 24. Apertures 72 are sized such that only the corners of optical portion 40, adjacent light capture surface 48, contact apertures 72 and thus light emitted from LEDs 24 which enters light capture surface 48 is not unduly influenced by the contact between apertures 72 and optical portion 40. In this manner, correct positioning of light capture surfaces 48 with respect to the light emitting surfaces of LEDs 24 is assured, despite minor variations in the manufacture and/or assembly of light pipes 36 and/or module 60.

Positioning member 68 can be fabricated from any suitable material, such as polycarbonate, which preferably has similar thermal expansion characteristics as the material from which light pipes 36 are fabricated. Positioning member 68 also provides mount posts 84 to which the mounting points 64 of light pipe modules 60 can be fastened to complete the locating and mounting of light pipes 36.

As best seen in FIG. 1, light pipes 36 of light engine 20 can be arranged in two or more modules 60, each of which are positioned by positioning member 68 to provide different components of the light beam patterns desired to be produced by the lighting element that light engine 20 is employed in. Light pipes 36 of a module 60, or from two or more modules 60, can be activated in groups t provide different components of desired light beam patterns.

For example, one group can provide light used in a low beam headlamp pattern, while a second group can provide light used in a high beam headlamp pattern and a third group can provide steering light, i.e.—side light which is adaptively supplied or removed according to the steering position of the vehicle to illuminate the road over which the vehicle will pass as it is steered from a straight line. As will be apparent, LEDs 24 providing light through light pipes 36 in these groups can be illuminated or extinguished, as needed for the desired light patterns, either individually or in groups, as desired.

It is also contemplated that additional light pipes 36 can be provided in one or more of modules 60 to provide for the internationalization of lighting systems produced with light engine 20. For example, light engine 20 can include one or more light pipes 36 which are illuminated when light engine 20 is in a lighting system operated in a country with right hand drive cars and one or more light pipes 36 which are illuminated when light engine 20 is in a lighting system operated in a country with left hand drive cars.

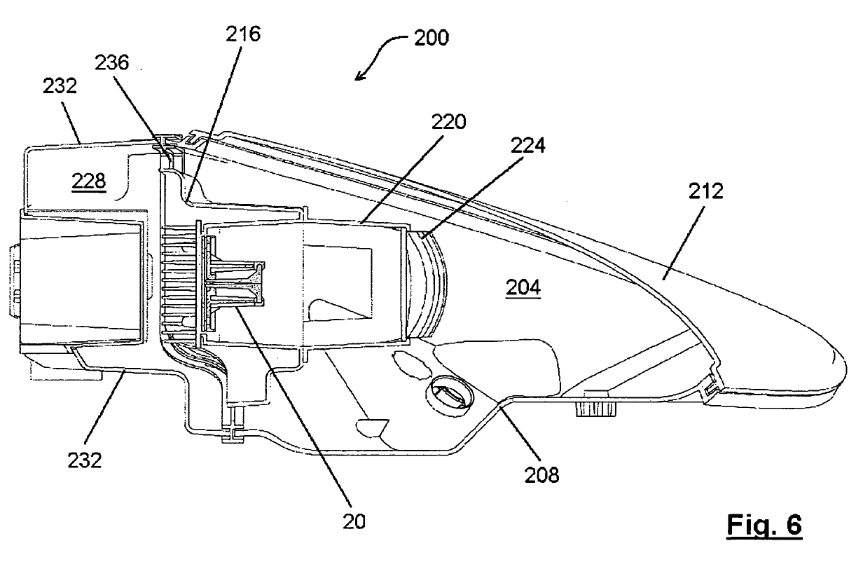

FIG. 6 shows an automotive lighting system 200, which in the illustrated embodiment is an automotive headlamp that employs light engine 20. Lighting system 200 is similar to that disclosed in co-pending U.S. patent application Ser. No. 11/729,693, entitled “Headlamp Assembly With Isolated Optics Chamber”, filed Mar. 29, 2007 and assigned to the assignee of the present invention and the contents of this application are incorporated by reference herein.

Lighting system 200 includes an optics chamber 204 which is formed from a base member 208 and a transparent cover member 212. Light engine 20 is mounted to a support bracket 216 and an optics support bracket 220 is also attached to support bracket 216 to position an optics system, comprising at least one lens 224, to receive the light emitted from light pipes 36 and to form that light into one or more desired beam patterns.

Optics chamber 204 is sealed and separated from a rear chamber 228, which is formed between a rear cover member 232, that is attached to base member 208 and cover member 212, by support bracket 216 and a flexible gasket 236, which allows support bracket 216 to be positioned to aim lens 224 and light engine 20, relative to base member 208 which is attached to the vehicle.

Heat sink 32 extends into rear chamber 228 and cooling air circulates through rear chamber 228 to remove waste heat from heat sink 32 when lighting system 200 is operating. The cooling air can be driven though rear chamber 228 by one or more electric cooling fans (not shown), or cooling air can be provided in any other suitable means as will occur to those of skill in the art.

As should now be apparent to those of skill in the art, the present invention provides a light engine for use in systems such as automotive lighting systems which employ two or more semiconductor light sources, such as LEDs. Light emitted from the light sources is captured by light pipes fabricated from optical glass and the light pipes are mounted such that the light capturing surface of each light pipe is properly positioned, with respect to the semiconductor light source, to efficiently capture and transfer the light emitted from the semiconductor light source. The light pipes transfer substantially all of the light captured from the semiconductor light sources to their respective light emitting surfaces which can be appropriately located adjacent the output optics of the lighting system. The light engine can be easily assembled as the light pipes are arranged in modules wherein a carrier is molded over a portion of the light pipes to fix the light pipes into their desired positions.

The above-described embodiments of the invention are intended to be examples of the present invention and alterations and modifications may be effected thereto, by those of skill in the art, without departing from the scope of the invention which is defined solely by the claims appended hereto.

What is claimed is:

1. A light engine comprising:
at least two semiconductor light sources;
a heat sink in thermal communication with the at least two semiconductor light sources to remove waste heat therefrom;
a positioning member including a set of positioning apertures, the positioning member mounted with respect to the at least two semiconductor light sources such that respective positioning apertures are closely aligned with corresponding light emitting surfaces of the at least two semiconductor light sources; and
a light pipe module comprising at least two light pipes, each light pipe including an optical portion, having a light capturing surface and a light emitting surface, and a non-optical portion to mount the light pipe, the light pipe module including a carrier member formed over the non-optical portion of each light pipe, the carrier member maintaining the light pipes in a desired orientation and having a mounting portion to engage the positioning member such that the light capturing surface of each light pipe in the module is positioned in a respective positioning aperture adjacent the light emitting surface of the semiconductor light source.

2. The light engine of claim 1 wherein the light pipes are formed from optical glass and the carrier member is overmolded on the non-optical portion.

3. The light engine of claim 2 wherein the non-optical portion includes a feature to enhance engagement of the light pipe with the carrier member.

4. The light engine of claim 1 wherein the optical portions of the light pipes have a rectangular cross section and the positioning apertures are sized and shaped to engage only the corners of the cross section of the light pipes to position the light capture surface of the light pipes.

5. The light engine of claim 1 wherein the light emitting surface has a lip formed on at least one edge of the light emitting surface, the lip extending the radii between the light emitting surface and the adjacent side of the light pipe outside of the surface region of the light emitting surface from which light is expected to be emitted.

6. A light engine according to claim 1 wherein the at least two semiconductor light sources are mounted to a planar substrate which includes electrical circuitry to provide power to the semiconductor light sources, the planar substrate being mounted to, and in thermal communication with, the heat sink.

7. A light engine according to claim 1 wherein the heat sink includes a set of cooling fins upstanding from the side of the heat sink opposite the side which is in thermal communication with the semiconductor light sources.

8. A light engine according to claim 1 wherein the at least two semiconductor light sources are light emitting diodes.

9. A light engine according to claim 1 wherein the set of light pipes includes at least two light pipes with light emitting surfaces of different dimensions to provide light from the respective semiconductor light sources in different patterns.

10. An automotive lighting system, comprising:
a base member;
a transparent cover member joined to the base member and forming an optics chamber therebetween;
a rear cover joined to the base member and cover member to form a rear chamber adjacent the optics chamber;
a mounting bracket and flexible moveably attached to the base member, the mounting bracket having mounted to it a light engine and an optics system, the mounting bracket, flexible gasket and light engine separating the optics chamber from the rear chamber and the light engine comprising:
at least two semiconductor light sources;
a heat sink in thermal communication with the at least two semiconductor light sources to remove waste heat therefrom;
a positioning member including a set of positioning apertures, the positioning member mounted with respect to the at least two semiconductor light sources such that respective positioning apertures are closely aligned with corresponding light emitting surfaces of the at least two semiconductor light sources; and
a light pipe module comprising at least two light pipes, each light pipe including an optical portion, having a light capturing surface and a light emitting surface, and a non-optical portion to mount the light pipe, the light pipe module including a carrier member formed over the non-optical portion of each light pipe, the carrier member maintaining the light pipes in a desired orientation and having a mounting portion to engage the positioning member such that the light capturing surface of each light pipe in the module is positioned in a respective positioning aperture adjacent the light emitting surface of the semiconductor light source.

11. A light engine comprising:
one or more semiconductor light sources;
a positioning member including a set of positioning apertures, the positioning member mounted with respect to said one or more semiconductor light sources such that respective positioning apertures are closely aligned with corresponding light emitting surfaces of the one or more semiconductor light sources;
a light pipe module having one or more light pipes, each light pipe including an optical portion, having a light capturing surface and a light emitting surface, and a non-optical portion to mount the light pipe, the light pipe module including a carrier member formed over the non-optical portion of each light pipe, the carrier member maintaining the light pipes in a desired orientation and having a mounting portion to engage the positioning member such that the light capturing surface of each light pipe in the module is positioned in a respective positioning aperture adjacent the light emitting surface of the semiconductor light source; and
a lip extending radii between the light emitting surface and the adjacent side of the light pipe outside of the surface region of the light emitting surface from which light is expected to be emitted.

12. A light engine according to claim 11 wherein said one or more semiconductor light sources are mounted to a planar substrate which includes electrical circuitry to provide power to the one or more semiconductor light sources, the planar substrate being mounted to, and in thermal communication with a heat sink in thermal communication with said one or more light semiconductor light sources.

13. A light engine according to claim 11 further comprising a heat sink in thermal communication with said one or more light sources to remove waste heat therefrom, wherein the heat sink includes a set of cooling fins upstanding from the side of the heat sink opposite the side which is in thermal communication with the one or more semiconductor light sources.

14. A light engine according to claim 11 wherein one or more semiconductor light sources are light emitting diodes.

15. A light engine according to claim 11 wherein the set of light pipes includes at least two light pipes with light emitting surfaces of different dimensions to provide light from the respective semiconductor light sources in different patterns.
